(19) United States
(12) Patent Application Publication
(10) Pub. No.: US 2024/0347503 A1
(43) Pub. Date: Oct. 17, 2024

(54) SEMICONDUCTOR STRUCTURE AND METHOD FOR FABRICATING THE SAME

(71) Applicant: UNITED MICROELECTRONICS CORP., Hsinchu (TW)

(72) Inventors: Shing-Ren SHEU, Taoyuan City (TW); Kai-Kuang HO, Hsinchu City (TW); Yu-Jie LIN, Taichung City (TW); Kuo-Ming CHEN, Hsinchu County (TW); Yi-Feng HSU, Hsinchu City (TW)

(21) Appl. No.: 18/201,976

(22) Filed: May 25, 2023

(30) Foreign Application Priority Data
Apr. 12, 2023 (TW) 112113617

(51) Int. Cl. H01L 23/00; H01L 23/498

(52) U.S. Cl. CPC H01L 24/94; H01L 23/49816; H01L 24/04; H01L 24/13; H01L 24/48; H01L 24/73; H01L 2224/0401; H01L 2224/13023; H01L 2224/48453; H01L 2224/73207; H01L 2224/94

(57) ABSTRACT

A semiconductor structure and a method for fabricating the same are provided. The semiconductor structure includes a first chip, a second chip and a conductive structure. The first chip has an active side and an opposite side disposed opposite to each other. The second chip includes a chip bonding portion and an outer pad, and the outer pad is located outside the chip bonding portion. The first chip is disposed on the chip bonding portion of the second chip with the active side. The conductive structure is disposed on the outer pad, and the conductive structure includes a stack of a plurality of metal balls. The stack extends from the outer pad beyond the opposite side of the first chip.

This application claims the benefit of Taiwan application Serial No. 112113617, filed Apr. 12, 2023, the subject matter of which is incorporated herein by reference.

### TECHNICAL FIELD

This disclosure relates to a semiconductor structure and a method for fabricating the same, in particular to a semiconductor structure including a conductive structure of a stack of a plurality of metal balls and a method for fabricating the same.

### BACKGROUND

As the demand for electronic products tends toward high functionality, high-speed signal transmission, and high density of electronic components, the packaging technology gradually tends toward multi-chip module package. How to produce 3D stack package in a cost effective way has become one of the goal of the industry.

### SUMMARY

This disclosure relates to a semiconductor structure and a method for fabricating the same. The conductive structure including a stack of metal balls as I/O paths for multi-chip stack effectively reduces process complexity and saves costs.

According to one aspect of the present disclosure, a semiconductor structure is provided. The semiconductor structure includes a first chip, a second chip and a conductive structure. The first chip has an active side and an opposite side disposed opposite to each other. The second chip includes a chip bonding portion and an outer pad located outside the chip bonding portion. The first chip is disposed on the chip bonding portion of the second chip with the active side. The conductive structure is disposed on the outer pad and includes a stack of a plurality of metal balls. The stack extends from the outer pad beyond the opposite side of the first chip.

According to another aspect of the present disclosure, a method for fabricating a semiconductor structure is provided. The method includes the following steps. First, a plurality of first chips is singularized from a first wafer, and each first chip has an active side and an opposite side disposed opposite to each other. Next, a second wafer is provided, the second wafer has a plurality of predetermined zones within which a chip bonding portion and an outer pad are located, and the outer pad is located outside the chip bonding portion. Then, the active side of each first chip is bonded to the chip bonding portion within each predetermined zone. Afterwards, a conductive structure is formed on the outer pad within each predetermined zone, each conductive structure includes a stack of a plurality of metal balls, and each stack extends from the outer pad beyond the opposite side of each first chip.

The above and other aspects of the disclosure will become better understood with regard to the following detailed description of the preferred but non-limiting embodiment(s). The following description is made with reference to the accompanying drawings.

### BRIEF DESCRIPTION OF THE DRAWINGS

FIG. 1 is a cross-sectional view of a semiconductor die according to one embodiment of the present disclosure.

FIGS. 2A-21 exemplarily show a method for fabricating the semiconductor die of FIG. 1 according to one embodiment of the present disclosure.

FIG. 3 is a cross-sectional view of a semiconductor package structure according to another embodiment of the present disclosure.

FIGS. 4A-4C exemplarily show a method for fabricating the semiconductor package structure of FIG. 3 according to another embodiment of the present disclosure.

### DETAILED DESCRIPTION

The present disclosure provides a conductive structure including a stack of metal balls as I/O paths for multi-chip stack, which effectively reduces process complexity and saves costs.

Each embodiment of the present disclosure will be described in detail hereinafter, and illustrated with drawings. In addition to these detailed descriptions, the disclosure may be broadly implemented in other embodiments, and any easily substituted, modified, or equivalent variations of the described embodiments are included within the scope of the present disclosure, which is subject to the scope of the claims thereafter. In the description of the specification, many specific details and examples of embodiments are provided in order to provide the reader with a more complete understanding of the disclosure; however, these specific details and examples of embodiments should not be considered as limitations of the disclosure. In addition, well-known steps or elements are not described in detail to avoid unnecessary limitations of the present disclosure.

It should be noted that the drawings of the present disclosure are simplified in order to clearly illustrate the contents of the embodiments and to highlight the features of the present disclosure, and the dimensions on the drawings are not drawn to the same scale as the actual product. Accordingly, the specification and the drawings are for the purpose of describing the embodiments only and are not intended to limit the scope of the disclosure. Identical or similar element symbols are used to represent identical or similar elements.

In addition, the terms such as “first”, “second”, “third”, etc. used in the specification and the claims are for the purpose of distinguishing different elements, and they do not imply and represent any previous sequence of the elements, nor do they represent the sequence of an element and another element, or the sequence of the manufacturing method, and the use of these terms is only for the purpose of making a clear distinction between an element with a certain name and another element with the same name.

Besides, for the sake of description, the terms such as “underneath”, “below”, “under”, “above”, “over”, “on”, and other spatial relative terms are used to describe the relationship between one element or feature and other element(s) or feature(s) as shown in the drawings. The spatial relative term is intended to cover different orientations of the element in use or operation, in addition to the orientation shown in the drawings. The element may be oriented in other ways, such as rotated 90 degrees or in other orientations, and again, the spatial relative term used herein may be interpreted accordingly.

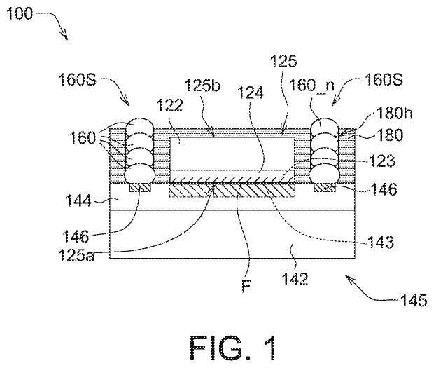

FIG. 1 is a cross-sectional view of a semiconductor die 100 according to one embodiment of the present disclosure. Referring to FIG. 1, the semiconductor die 100 may not be a single chip 3D semiconductor structure. For example, the semiconductor die 100 may include two chips, i.e., a first chip 125 and a second chip 145, but the present disclosure is not limited thereto. For example, in other embodiments, the semiconductor die 100 may include a plurality of first chips 125 stacked one on another and disposed on the second chip 145.

The first chip 125 may include a first substrate 122 and a first element layer 124 on the first substrate 122. The second chip 145 may include a second substrate 142 and a second element layer 144 on the second substrate 142. The first substrate 122 and the second substrate 142 may be semiconductor substrates, such as silicon substrates. The second chip 145 may be larger in size than the first chip 125.

The first chip 125 may include a chip bonding layer 123 formed on the first element layer 124; the second chip 145 may include a chip bonding portion 143 formed on the second element layer 144. In some embodiments, the first chip 125 and the second chip 145 are bonded to each other in a face-to-face manner at the bonding surface F. For example, the first chip 125 may have an active side 125a and an opposite side 125b disposed opposite to each other. The active side 125a is located at the chip bonding layer 123, and the opposite side 125b is located at the first substrate 122. The first chip 125 is disposed on the chip bonding portion 143 of the second chip 145 with the active side 125a so as to be bonded to the second chip 145.

In one particular embodiment, the bonding may be a hybrid bonding. Here, the chip bonding layer 123 and the chip bonding portion 143 may each include a metal bonding structure and a dielectric material structure. The metal bonding structure of the chip bonding layer 123 may be bonded to the metal bonding structure of the chip bonding portion 143 by metal-to-metal bonding; the dielectric material structure of the chip bonding layer 123 may be bonded to the dielectric material structure of the chip bonding portion 143 by fusion bonding. Thus, the bonding surface F may be both a metal-to-metal bonding structure and a dielectric material-to-dielectric material bonding structure. In this way, the first element layer 124 of the first chip 125 may be electrically connected to the second element layer 144 of the second chip 145 to form an electrical connection between the first chip 125 and the second chip 145 across the bonding surface F to transmit electrical signals between the first chip 125 and the second chip 145.

As shown in FIG. 1, the second chip 145 may further include an outer pad 146. The outer pad 145 is located outside the chip bonding portion 143. In one embodiment, the outer pad 146 may be formed together with the chip bonding portion 143. For example, the outer pad 146 may be formed simultaneously with the metal bonding structure of the chip bonding portion 143. When the metal bonding structure of the chip bonding portion 143 is a copper (Cu) bonding structure, the outer pad 146 is a Cu bonding pad. In addition, the outer pad 146 is further electrically connected to the chip bonding portion 143.

The semiconductor die 100 may further include a conductive structure 160S disposed on the outer pad 146. As shown in FIG. 1, the conductive structure 160S may include one or more stacks. The one or more stacks may be a stack or stacks of metal balls 160 upwardly stacked one on another from the outer pad 146 and extending beyond the opposite side 125b of the first chip 125. For example, the semiconductor die 100 may further include an insulation structure 180 covering the first chip 125. The insulation structure 180 may have through hole 180h with a number corresponding to that of the stack of the metal balls 160. The stack of the metal balls 160 is located in one of the through hole 180h and protrudes beyond the insulation structure 180 to expose an end metal ball 160_n of the stack from the insulation structure 180. In this way, the conductive structure 160S serves as an I/O path for the semiconductor die 100, thereby enabling the transmission of electrical signals to/from the semiconductor die 100.

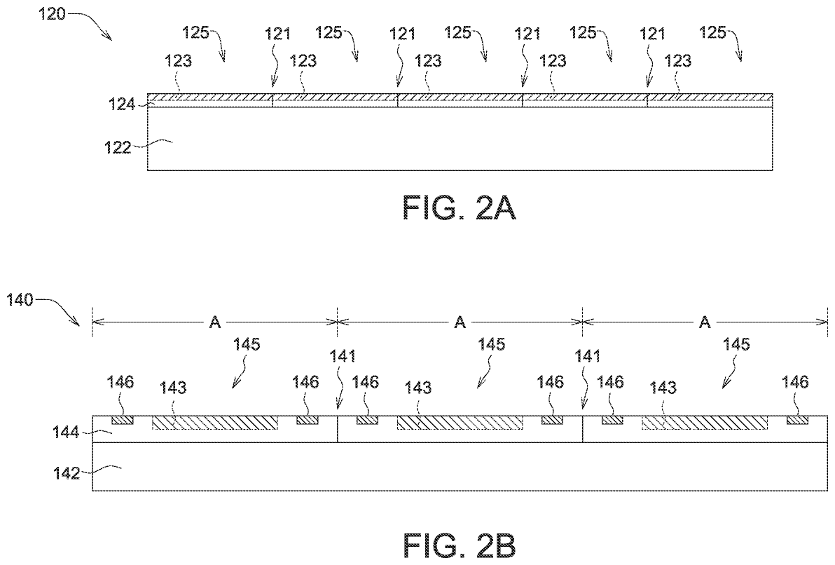

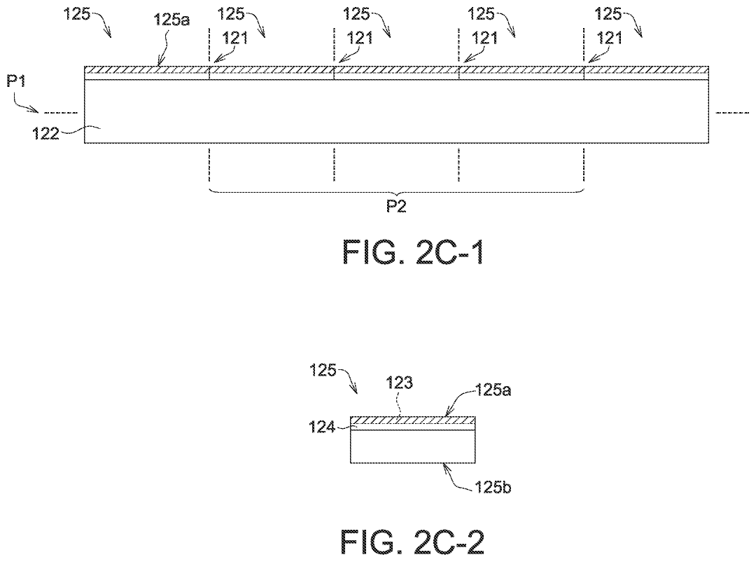

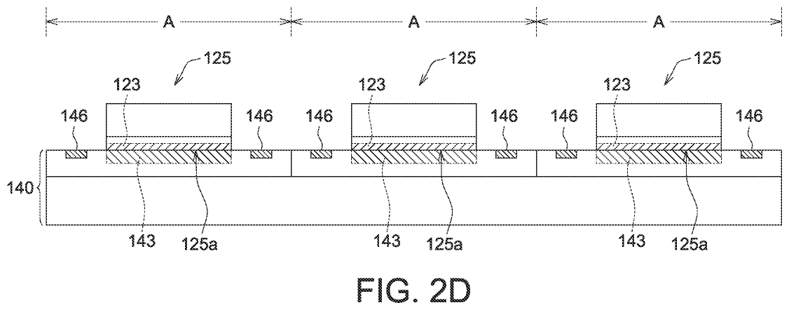

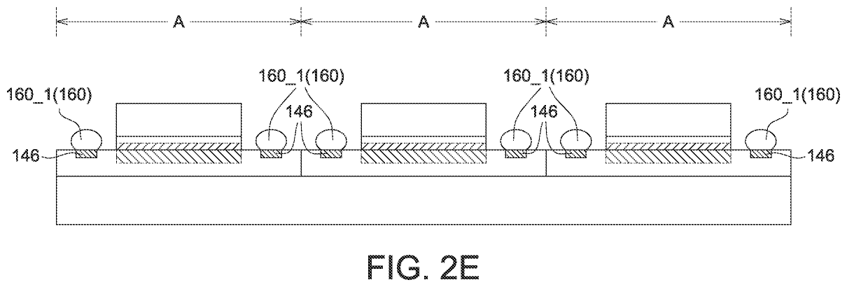

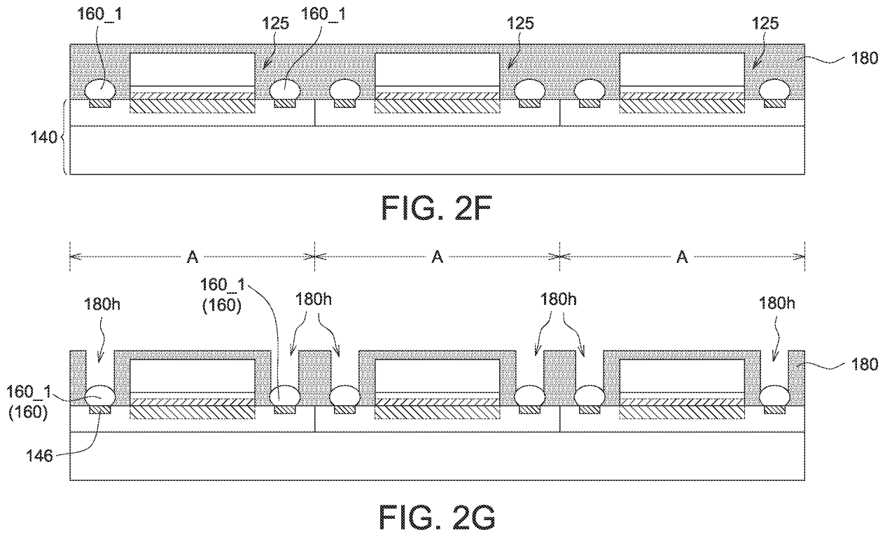

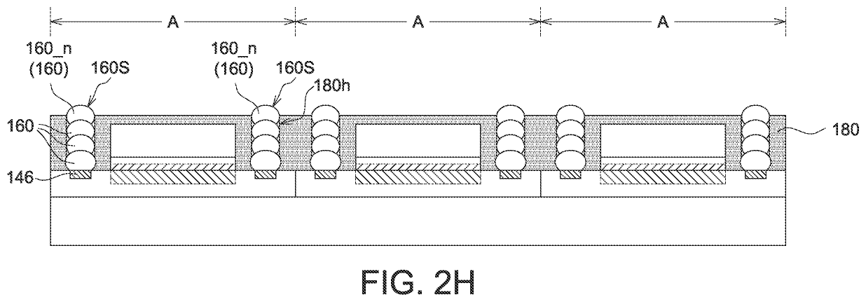

FIGS. 2A-21 exemplarily show a method for fabricating the semiconductor die 100 of FIG. 1 according to one embodiment of the present disclosure.

Referring to FIG. 2A, a first wafer 120 is provided. The first wafer 120 includes a first substrate 122, a first element layer 124 formed on the first substrate 122 and a chip bonding layer 123 formed on the first element layer 124. The first wafer 120 has a plurality of dicing lanes 121 to define areas of the first chips 125.

Referring to FIG. 2B, a second wafer 140 is provided. The second wafer 140 includes a second substrate 142, a second element layer 144 formed on the second substrate 142 and a chip bonding portion 143 and an outer pad 146 formed on the second element layer 144. The second wafer 140 has a plurality of dicing lanes 141 separating a plurality of predetermined zones A to define areas of the second chips 145. One chip bonding portion 143 and at least one outer pad 146 are provided in each predetermined zone A. As previously mentioned, the outer pad 146 may be formed together with the chip bonding portion 143 and will not be repeated here.

Referring to FIG. 2C-1, a thinning process P1 is performed on the first wafer 120 to reduce the thickness of the first substrate 122, but the present disclosure is not limited thereto. In other embodiment, the thinning process P1 may be omitted.

Referring to FIG. 2C-1 and FIG. 2C-2, a singularization process P2 is performed on the first wafer 120 along the dicing lanes 121 to singularize the first chips 125 from the first wafer 120.

Referring to FIG. 2D, the chip bonding layers 123 of the first chips 125 are bonded to the chip bonding portions 143 within the predetermined zones A of the second wafer 140, so that each first chip 125 is disposed on the chip bonding portion 143 with the active side 125a facing the second wafer 140.

Referring to FIG. 2E, the first metal ball 160_1 is formed on each outer pad 146. Next, referring to FIG. 2F, an insulation structure 180 is formed on the second wafer 140 and covers the first chip 125 and the first metal ball 160_1. The insulation structure 180 may be, but is not limited to, a packaging material such as a molding compound, or a dielectric layer containing silicon dioxide.

Then, referring to FIG. 2G, the through holes 180 are formed through the insulation structure 180 at positions each corresponding to the outer pad 146 within each predetermined zone A. The through hole 180h may be formed, for example, by laser or etching. In addition, the depth of the through hole 180h may not extend through the whole insulation structure 180, but terminate at the first metal ball 160_1.

Referring to FIG. 2H, the metal balls 160 are formed successively on the first metal ball 160_1 in each through hole 180h, and stacked one on another to form a stack of the metal balls 160, and the stack extends beyond the insulation structure 180. As shown in the figure, the stack protrudes beyond the insulation structure 180 to expose an end metal ball 160_n from the insulation structure 180, thereby forming a conductive structure 160S on the outer pad 146 within each predetermined zone A.

In the present embodiment, the first metal ball 160_1 is formed on the outer pad 146 at the first step, and then the through hole 180h is formed. Next, the metal balls 160 stacked one on another are formed in the through hole 180h. However, the present disclosure is not limited to the embodiment. For example, instead of forming the first metal ball 160_1 on the outer pad 146 at the first step, the metal balls 160 stacked one on another in the through hole 180h may be formed on the outer pad 146 after the through hole 180h through the insulation structure 180 is formed to expose the out pad 146.

After the conductive structure 160S is formed, referring to FIG. 2I, perform a sawing process P3 on the insulation structure 180 and the second wafer 140 corresponding to the positions of the predetermined zones A to form a plurality of semiconductor dies 100 as shown in FIG. 1.

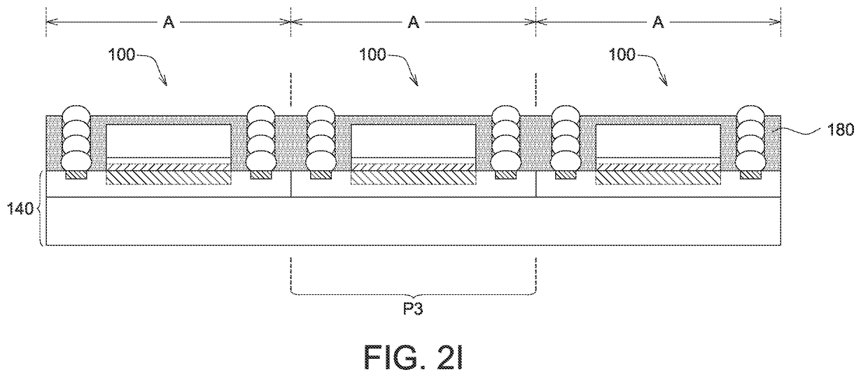

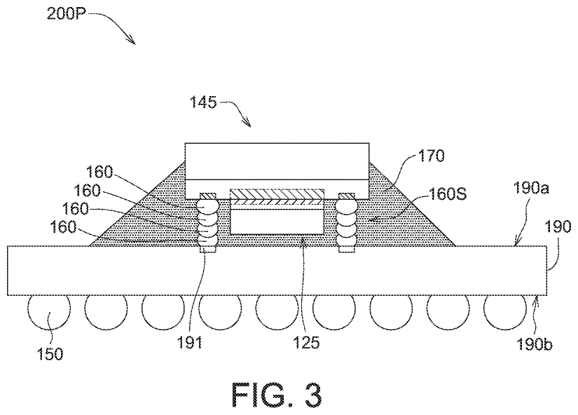

FIG. 3 is a cross-sectional view of a semiconductor package structure 200P according to another embodiment of the present disclosure. Referring to FIG. 3, some differences from the embodiment of FIG. 1 are that the semiconductor package structure 200P does not have an insulation structure 180, but rather is packaged with an underfill layer 170 between the first chip 125, the second chip 145 and a carrier board 190 which the conductive structure 160S is connected to in an inverted manner.

The carrier board 190 may be a printed circuit board or substrate, having a first side 190a and a second side 190b disposed opposite to each other. The carrier board 190 is provided with a solder pad 191 and a plurality of conductive terminals 150 (e.g., solder balls). The solder pad 191 is located on the first side 190a of the carrier board 190 and the conductive terminals 150 are located on the second side 190b of the carrier board 190. The conductive structure 160S may be directly connected to the solder pad 191 in an inverted manner.

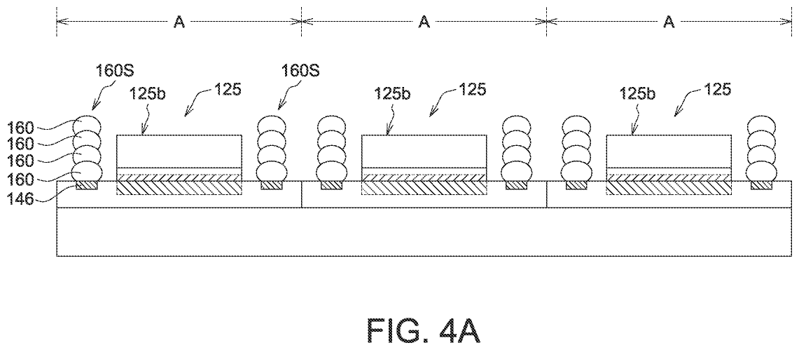

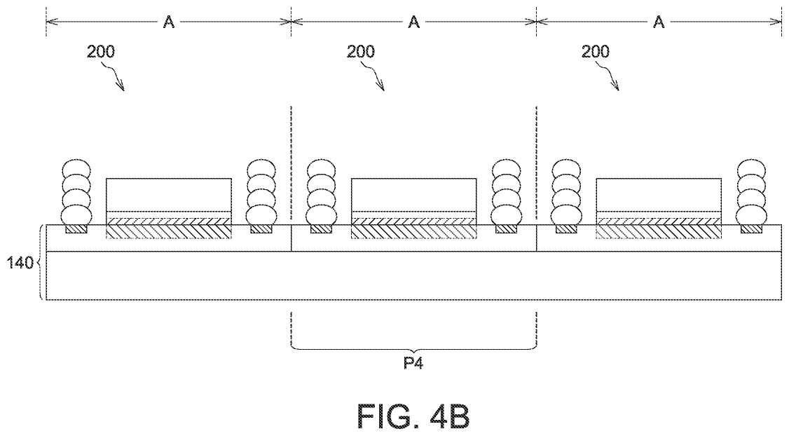

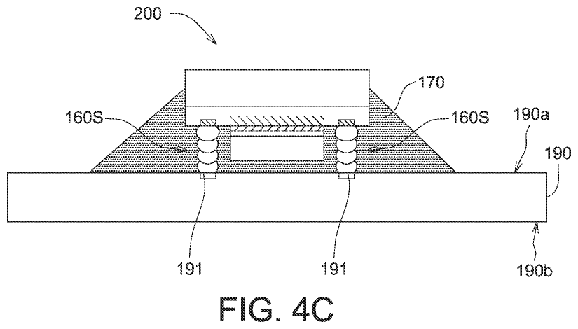

FIGS. 4A-4C exemplarily show a method for fabricating the semiconductor package structure 200P of FIG. 3 according to another embodiment of the present disclosure.

It is noted that the process shown in FIG. 4A follows the process in FIG. 2D. That is, the processes of FIG. 2A to FIG. 2D are also applicable to forming the semiconductor package structure 200P of FIG. 3. As shown in FIG. 2D, the process of FIG. 4A is performed next after each first chip 125 is disposed on the chip bonding portion 143 with the active side 125a facing the second wafer 140.

Referring to FIG. 4A, the metal balls 160 stacked one on another are formed on each outer pad 146 to form a stack of metal balls 160, and the stack extends beyond the opposite side 125b of the first chip 125, thereby forming a conductive structure 160S on the outer pad 146 within each predetermined zone A.

After the conductive structure 160S is formed, referring to FIG. 4B, a sawing process P4 is performed on the second wafer 140 corresponding to the positions of the predetermined zones A to form a plurality of single structures 200.

Next, referring to FIG. 4C, a carrier board 190 is provided, and one of the single structures 200 is connected to the carrier board 190 in an inverted manner. In other words, the single structure 200 is connected to the solder pad 191 located on the first side 190a of the carrier board 190 by the conductive structure 160S. Subsequently, an underfill layer 170 is filled between the single structure 200 and the carrier board 190, and the underfill layer 170 at least surrounds the conductive structure 160S.

Then, a plurality of conductive terminals 150 are formed on the second side 190b of the carrier board 190, as shown in FIG. 3, to form the semiconductor package structure 200P, so that the semiconductor package structure 200P may be electrically connected to the external components through the conductive terminals 150.

It is worth mentioning that in each of the aforementioned embodiments, the metal balls 160 may be formed on the outer pad 146 by wire bonding, such as but not limited to gold ball, silver ball, etc. Since wire bonding is a mature process in the industry, forming the I/O path of the semiconductor structure by wire bonding may effectively reduce the complexity and cost of the process compared to the general process (e.g., micro-bumping and through-silicon-via) for making the I/O path of a 3D stacked semiconductor structure, and does not affect the electrical performance of the peripheral components.

It will be apparent to those skilled in the art that various modifications and variations can be made to the disclosed embodiments. It is intended that the specification and examples be considered as exemplary only, with a true scope of the disclosure being indicated by the following claims and their equivalents.

What is claimed is:

1. A semiconductor structure comprising:
a first chip having an active side and an opposite side disposed opposite to each other;
a second chip comprising a chip bonding portion and an outer pad located outside the chip bonding portion, the first chip disposed on the chip bonding portion of the second chip with the active side; and
a conductive structure disposed on the outer pad, the conductive structure comprising a stack of a plurality of metal balls, the stack extending from the outer pad beyond the opposite side of the first chip.

2. The semiconductor structure according to claim 1, wherein the metal balls are formed by wire bonding.

3. The semiconductor structure according to claim 1, further comprising an insulation structure covering the first chip, wherein the insulation structure has a through hole in which the stack of the metal balls is located.

4. The semiconductor structure according to claim 3, wherein the stack of the metal balls protrudes beyond the insulation structure.

5. The semiconductor structure according to claim 1, further comprising a carrier board having a first side and a second side disposed opposite to each other, wherein the conductive structure is connected to the first side of the carrier board.

6. The semiconductor structure according to claim 5, further comprising an underfill layer located between the first chip, the second chip and the carrier board, and at least surrounding the conductive structure.

7. The semiconductor structure according to claim 5, further comprising a plurality of conductive terminals disposed on the second side of the carrier board.

8. The semiconductor structure according to claim 1, wherein the second chip is larger in size than the first chip.

9. The semiconductor structure according to claim 1, wherein the outer pad is formed together with the chip bonding portion.

10. A method for fabricating a semiconductor structure comprising:
singularizing a plurality of first chips from a first wafer, each of the first chips having an active side and an opposite side disposed opposite to each other;
providing a second wafer having a plurality of predetermined zones within which a chip bonding portion and an outer pad are located, the outer pad located outside the chip bonding portion;
bonding the active side of each of the first chips to the chip bonding portion within each of the predetermined zones; and
forming a conductive structure on the outer pad within each of the predetermined zones, the conductive structure comprising a stack of a plurality of metal balls, the stack extending from the outer pad beyond the opposite side of each of the first chips.

11. The method according to claim 10, wherein the metal balls are formed by wire bonding.

12. The method according to claim 10, further comprising performing a thinning process of the first wafer prior to singularizing the first chips.

13. The method according to claim 10, wherein forming the conductive structure on the outer pad within each of the predetermined zones comprises:
forming an insulation structure covering the first chips;
forming a plurality of through holes passing through the insulation structure corresponding to the outer pad within each of the predetermined zones; and
forming the metal balls stacked one on another in each of the through holes to form the stack of the metal balls of the conductive structure.

14. The method according to claim 13, wherein the stack of the metal balls protrudes beyond the insulation structure.

15. The method according to claim 13, further comprising sawing the insulation structure and the second wafer corresponding to the predetermined zones to form a plurality of semiconductor dies.

16. The method according to claim 10, further comprising sawing the second wafer after forming the conductive structures corresponding to the predetermined zones to form a plurality of single structures.

17. The method according to claim 16, further comprising:
providing a carrier board having a first side and a second side disposed opposite to each other; and
connecting the conductive structure of one of the single structures to the first side of the carrier board.

18. The method according to claim 17, further comprising filling an underfill layer between one of the single structures and the carrier board, wherein the underfill layer at least surrounds the conductive structure.

19. The method according to claim 17, further comprising forming a plurality of conductive terminals on the second side of the carrier board.

20. The method according to claim 10, wherein the outer pad is formed together with the chip bonding portion.
